(19) United States
(12) Patent Application Publication
(10) Pub. No.: US 2015/0070672 A1
(43) Pub. Date: Mar. 12, 2015

(54) LIGHT EXPOSURE METHOD, LIGHT EXPOSURE DEVICE, AND REFLECTIVE PROJECTION LIGHT EXPOSURE MASK

(71) Applicant: Kabushiki Kaisha Toshiba, Tokyo (JP)

(72) Inventors: Takamasa TAKAKI, Kanagawa-ken (JP); Satoshi TANAKA, Kanagawa-ken (JP)

(73) Assignee: KABUSHIKI KAISHA TOSHIBA, Tokyo (JP)

(21) Appl. No.: 14/162,019

(22) Filed: Jan. 23, 2014

(30) Foreign Application Priority Data
Sep. 10, 2013 (JP) 2013-187660

(51) Int. Cl. G03F 1/52; G03F 1/24; G03F 7/20

(52) U.S. Cl. CPC G03F 1/52; G03F 7/2045; G03F 1/24
USPC 355/67; 355/77; 430/5

(57) ABSTRACT

According to one embodiment, a light exposure method includes irradiating light on a reflective projection light exposure mask and irradiating an object to be exposed to light with reflected light by reflecting the light by the reflective projection light exposure mask. The reflective projection light exposure mask includes a substrate and a pattern portion. The substrate has a first surface. The pattern portion has a multilayer reflective film provided on the first surface of the substrate. The pattern portion includes a plurality of protruding patterns and depression patterns. The depression patterns are provided between the plurality of protruding patterns.

### CROSS-REFERENCE TO RELATED APPLICATIONS

This application is based upon and claims the benefit of priority from Japanese Patent Application No. 2013-187660, filed on Sep. 10, 2013; the entire contents of which are incorporated herein by reference.

### FIELD

Embodiments described herein relate generally to a light exposure method, a light exposure device and a reflective projection light exposure mask.

### BACKGROUND

In reflective projection light exposure, light is irradiated on the mask surface of a reflective projection light exposure mask, and the reflected light of that light is projected to the object to be exposed to light. The light is incident on the reflective projection light exposure mask with the main light axis inclined with respect to the mask surface. In order to form a fine pattern, it is necessary that the optical system has a high numerical aperture (NA).

When an optical system with a high NA is used, the incident angle of the light with respect to the mask surface is increased. Increasing the incident angle causes a reduction in the transfer performance (pattern image contrast, etc.), due to the effect of a change in reflectance properties according to the incident angle and a shadowing effect due to the thickness of the reflective mask pattern part (absorbent body). In reflective projection light exposure, it is important to improve the transfer performance.

### BRIEF DESCRIPTION OF THE DRAWINGS

FIG. 1A and FIG. 1B are schematic views illustrating a configuration of a reflective projection light exposure mask according to a first embodiment;

FIG. 2A to FIG. 2D illustrate the shadowing effect;

FIG. 3 is a schematic view illustrating the projection of the light reflected at the reflective projection light exposure mask;

FIG. 4A and FIG. 4B show a comparison between this embodiment and a reference example;

FIG. 5A and FIG. 5B show the intensity of optical images;

FIG. 6 shows the relationship between the position of the focal point and the shift of the image;

FIG. 7A and FIG. 7B illustrate the second embodiment;

FIG. 8 is a schematic view illustrating a configuration of a light exposure device according to the third embodiment; and

FIG. 9 is a flowchart illustrating the light exposure method according to the fourth embodiment.

### DETAILED DESCRIPTION

In general, according to one embodiment, a light exposure method includes irradiating light on a reflective projection light exposure mask and irradiating an object to be exposed to light with reflected light by reflecting the light by the reflective projection light exposure mask. The reflective projection light exposure mask includes a substrate and a pattern portion. The substrate has a first surface. The pattern portion has a multilayer reflective film provided on the first surface of the substrate. The pattern portion includes a plurality of protruding patterns and depression patterns. The depression patterns are provided between the plurality of protruding patterns.

Various embodiments will be described hereinafter with reference to the accompanying drawings. In the following description, the same reference numeral is applied to the same member, and for members that have been described once, the description is omitted as appropriate.

### First Embodiment

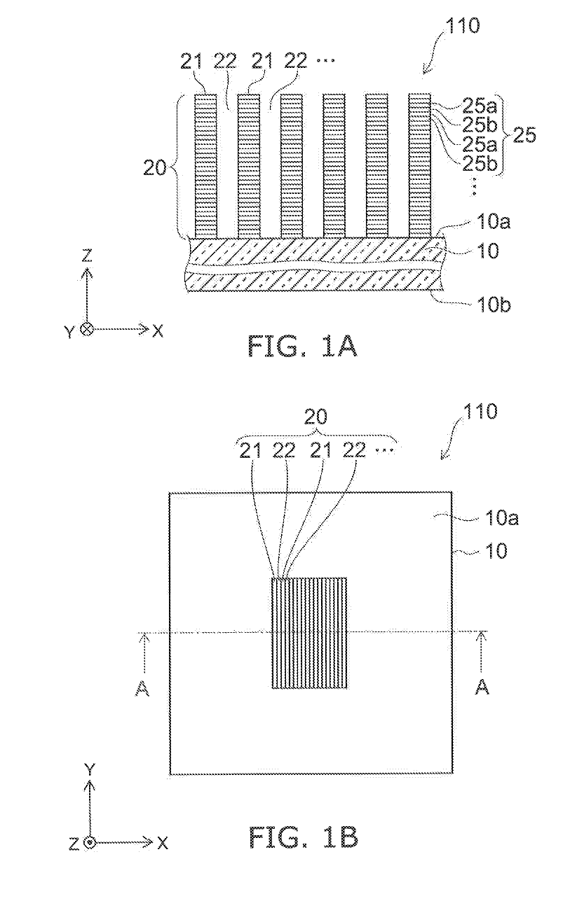

FIG. 1A and FIG. 1B are schematic views illustrating a configuration of a reflective projection light exposure mask according to a first embodiment.

FIG. 1A is a schematic cross-sectional view taken along the line A-A illustrated in FIG. 1B, FIG. 1B is a schematic plan view of a reflective projection light exposure mask 110. In FIG. 1A, an enlarged schematic cross-sectional view of a portion of the reflective projection light exposure mask 110 is illustrated.

As illustrated in FIGS. 1A and 1B, the reflective projection light exposure mask 110 according to this embodiment includes a substrate 10 and a pattern portion 20. Glass, for example, is used as the substrate 10. The substrate 10 includes a first surface 10a, and a second surface 10b on the opposite side to the first surface 10a. In this embodiment, the direction normal to the first surface 10a is the Z direction. Also, one of the directions normal to the Z direction is defined as the X direction, and the direction normal to the Z direction and the X direction is defined as the V direction.

The pattern portion 20 is provided on the first surface 10a of the substrate 10. The pattern portion 20 includes a multilayer reflective film 25. The pattern portion 20 includes a plurality of protruding patterns 21, and depression patterns 22 provided between the plurality of protruding patterns 21. The protruding patterns 21 and depression patterns 22 each extend in, for example, the Y direction. In other words, a line and space pattern configuration is configured by the protruding patterns 21 and the depression patterns 22. In this embodiment, a line and space pattern configuration is used as an example, but other pattern configurations (for example, an island configuration) may be used.

In the reflective projection light exposure mask 110, the protruding patterns 21 include a multilayer reflective film 25. The multilayer reflective film 25 is not included in the depression patterns 22. The first surface 10a of the substrate 10 is exposed on the bottom 22b of the depression patterns 22. If an etching stopper film (not shown on the drawings) is provided on the first surface 10a of the substrate 10, the first surface 10a includes an etching stopper film. In other words, the etching stopper film included in the first surface 10a is exposed on the bottom 22b of the depression patterns 22.

The multilayer reflective film 25 is a film that reflects light with a predetermined wavelength. In this embodiment, the multilayer reflective film 25 effectively reflects extreme ultraviolet (EUV). The wavelength of the EUV is, for example, not less than several nanometers (nm) and not more than several tens of nanometers. In this embodiment, EUV of 115 nanometers (nm) is used, for example.

The multilayer reflective film 25 includes, for example, a plurality of first films 25a and a plurality of second films 25b stacked alternately. Molybdenum (Mo) for example is used in the first film 25a. Silicon (Si) for example is used in the second film 25b.

The multilayer reflective film 25 includes, for example, several tens of pairs of the first film 25a and the second film 25b. In this embodiment, about 40 pairs of the first film 25a and the second film 25b are included. The film thickness of the first film 25a and the second film 25b are each, for example, about several nanometers. In this embodiment, the film thickness is not less than about 3 nm and not more than 4 nm. The total thickness of the multilayer reflective film 25 is, for example, 280 nm. Three or more types of films may be stacked alternately in the multilayer reflective film 25.

To manufacture the reflective projection light exposure mask 110, for example, an etching stopper film is formed on the first surface 10a of the substrate 10, and the multilayer reflective film 25 is formed on the etching stopper film. Then, a portion of the multilayer reflective film 25 is etched to the etching stopper film by, for example, reactive ion etching (RIE). In this way, the portion remaining without being etched becomes the protruding patterns 21, and the portion where the multilayer reflective film 25 is removed by etching becomes the depression patterns 22.

In the manufacture of the reflective projection light exposure mask 110, it is not necessary to provide a separate material for the bottom of the depression patterns 22, so the manufacturing process is simplified.

In reflective projection light exposure using the reflective projection light exposure mask 110, the shadowing effect is suppressed, and a high contrast pattern image is formed.

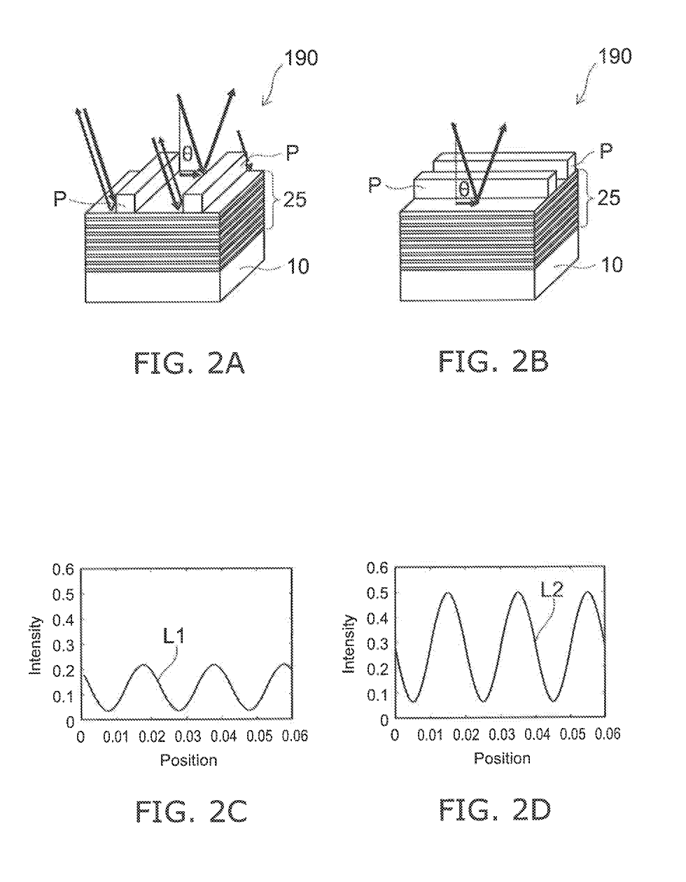

FIGS. 2A through 2D illustrate the shadowing effect.

In FIG. 2A, a schematic perspective view is illustrated of an example where light is incident at an inclination to the direction normal to the direction in which the pattern extends, and in FIG. 2B, a schematic perspective view is illustrated of an example where light is incident at an inclination to the direction in which the pattern extends. FIG. 2C shows the reflected light intensity as the line L1 when the light is incident as shown in FIG. 2A, and FIG. 2D shows the reflected light intensity as the line L2 when the light is incident as shown in FIG. 2B. The horizontal axis in FIG. 2C and FIG. 2D represents the position in the direction normal to the pattern, and the vertical axis represents the intensity.

A reflective projection light exposure mask 190 as illustrated in FIG. 2A and FIG. 2B includes the substrate 10, the multilayer reflective film 25 formed on the substrate 10, and a light absorbent pattern P provided on a portion of the multilayer reflective film 25.

As illustrated in FIG. 2A, when light is incident at an inclination to the direction normal to the direction in which the light absorbent pattern P extends, a portion of the light reflected at the multilayer reflective film 25 is blocked by the side surface of the light absorbent pattern P. On the other hand, as illustrated in FIG. 2B, when light is incident at an inclination to the direction in which the light absorbent pattern P extends, the light reflected at the multilayer reflective film 25 is reflected without being blocked by the side surface of the light absorbent pattern P. Therefore, the intensity of the reflected light shown in FIG. 2C (line L1) is lower than the intensity of the reflected light shown in FIG. 2D (line L2).

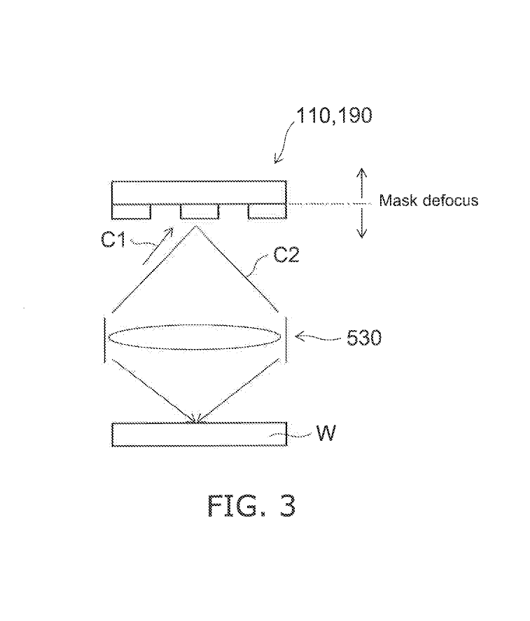

FIG. 3 is a schematic view illustrating the projection of the light reflected at the reflective projection light exposure mask.

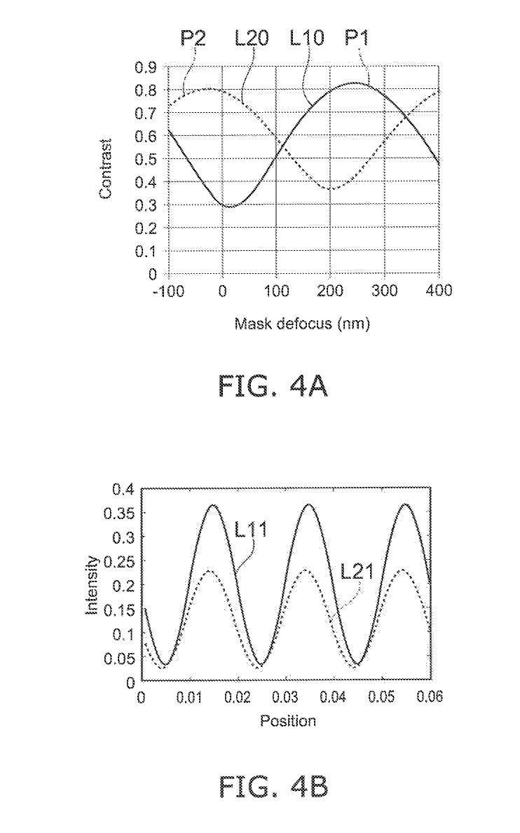

FIGS. 4A and 4B show a comparison between this embodiment and a reference example.

FIG. 4A shows the relationship between the focal point position and the contrast, and FIG. 4B shows the relationship between the position of intersection with the pattern and the contrast.

As illustrated in FIG. 3, the light C1 is incident on the reflective projection light exposure mask 110 and 190. The reflected light of the light C1 incident on the reflective projection light exposure mask 110 and 190 is the light C2. The light C1 is inclined at an angle of 8° for example with respect to the axis normal to the mask plane (the first surface 10a of the substrate 10) of the reflective projection light exposure mask 110 and 190. The reflected light C2 irradiates the object to be exposed to light via a projection optical system which is a second optical system 530. The object to be exposed to light is, for example, a wafer W on which a resist is applied.

FIG. 4A shows the results of a simulation of the variation in contrast when the position of the focal point of the light C1 is varied for the reflective projection light exposure masks 110 and 190. The horizontal axis of FIG. 4A represents the position of the focal point of the light C1 incident on the reflective projection light exposure masks 110 and 190, and the vertical axis represents the contrast of the reflected light C2.

In this embodiment, the position of the focal point is the position on the Z direction relative to the first surface 10a of the substrate 10. A positive position of the focal point represents upward from the first surface 10a (the opposite side to the substrate 10), and a negative position of the focal point represents downward from the first surface 10a (the substrate 10 side). Also, the contrast is represented by the following equation (1). In equation (1), Iₘₐₓ is the maximum value of the light intensity, and Iₘᵢₙ is the minimum value of the light intensity.

Contrast=(Iₘₐₓ−Iₘᵢₙ)/(Iₘₐₓ+Iₘᵢₙ) (1)

The line L10 shown in FIG. 4A is the contrast for the reflective projection light exposure mask 110, and the line L20 is the contrast for the reflective projection light exposure mask 190. Here, the thickness of the multilayer reflective film 25 is 280 nm. In the reflective projection light exposure mask 110, the protruding patterns 21 include the multilayer reflective film 25 with a thickness of 280 nm. The depression patterns 22 do not include the multilayer reflective film 25. In the reflective projection light exposure mask 190, the light absorbent pattern P is provided on a portion of the multilayer reflective film 25.

As shown in FIG. 4A, the position of the focal point of the peak P1 of the line L10 of the contrast for the reflective projection light exposure mask 110 is different from the position of the focal point of the peak P2 of the line L20 of the contrast for the reflective projection light exposure mask 190.

FIG. 4B shows the results of simulation of the optical image for the reflective projection light exposure masks 110 and 190. The horizontal axis of FIG. 4B shows the position in the direction normal to the pattern of the reflected light C2 in the reflective projection light exposure masks 110 and 190, and the vertical axis shows the intensity.

The line L11 shown in FIG. 4B is the intensity for the reflective projection light exposure mask 110, and the line L21 is the intensity for the reflective projection light exposure mask 190. It can be seen that the intensity for the reflective projection light exposure mask 110 as represented by the line L11 is greater than the intensity for the reflective projection light exposure mask 190 as represented by the line L21. In other words, it can be seen that, in the reflective projection light exposure mask 110, the transfer performance is superior compared with when the reflective projection light exposure mask 190 is used.

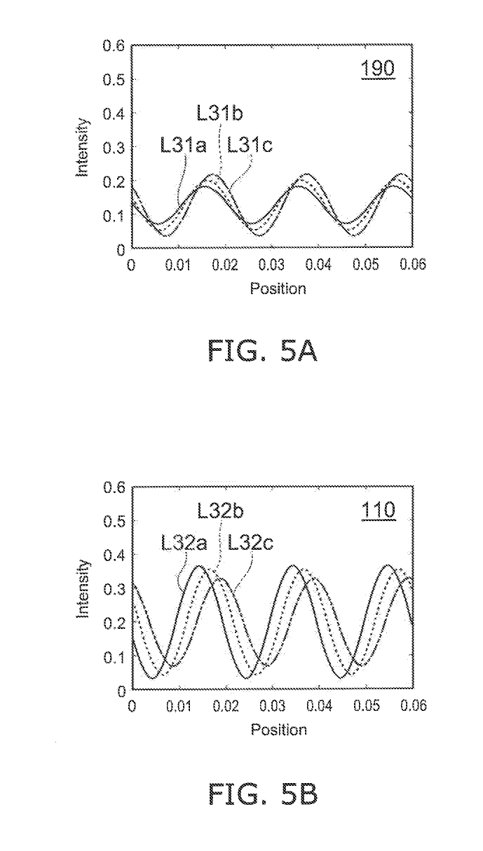

FIGS. 5A and 5B show the intensity of optical ages.

FIG. 5A shows the intensity of optical image due to the reflective projection light exposure mask 190. The horizontal axis of FIG. 5A represents the position in the direction normal to the pattern of the reflected light C2 for the reflective projection light exposure mask 190, and the vertical axis represents the intensity.

The line L31a shown in FIG. 5A is an example in which the position of the focal point of the light C1 is set to 250 nm, the line L31b is an example in which the position of the focal point of the light C1 is set to 300 nm, and the line L31c is an example in which the position of the focal point of the light C1 is set to 350 nm.

FIG. 5B shows the intensity of the optical image due to the reflective projection light exposure mask 110. The horizontal axis of FIG. 58 shows the position in the direction normal to the pattern of the reflected light C2 for the reflective projection light exposure mask 110, and the vertical axis shows the intensity. The line L32a shown in FIG. 5B is an example in which the position of the focal point of the light C1 is set to 250 nm, the line L32b is an example in which the position of the focal point of the light C1 is set to 300 nm, and the line L32c is an example in which the position of the focal point of the light C1 is set to 350 nm.

It can be seen that each of the lines L32a, L32b, and L32c shown in FIG. 5B have a greater intensity than the lines L31a, L31b, and L31c shown in FIG. 5A.

Also, it can be seen that the images when the reflective projection light exposure mask 110 and 190 are used shift depending on the position of the focal point, as shown by the lines L31a, L31b, and L31c of FIG. 5A and the lines L32a, L32b, and L32c of FIG. 5B.

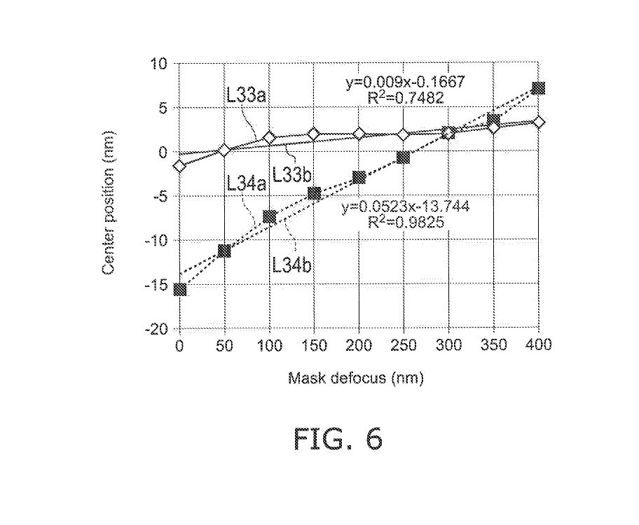

FIG. 6 shows the relationship between the position of the focal point and the shift of the image.

The horizontal axis of FIG. 6 represents the position of the focal point, and the vertical axis represents the amount of deviation of the position of the image in the direction normal to the pattern. The line L33a in FIG. 6 represents the relationship between the position of the focal point for the reflective projection light exposure mask 190 and the amount of deviation of the position of the image. The line L33b is a line that approximates the line L33a with a straight line. The line L34a represents the relationship between the position of the focal point for the reflective projection light exposure mask 110 and the amount of deviation of the position of the image. The line L34b is a line that approximates the line L34a with a straight line.

As shown in FIG. 6, in the reflective projection light exposure mask 110, the amount of deviation of the position of the image with respect to the position of the focal point is larger compared with that for the reflective projection light exposure mask 190. When the amount of deviation of the position with respect to the position of focal point is large, it is easy to use the position of the focal point as a monitor when setting.

In this way, by using the reflective projection light exposure mask 110, it is possible to improve the transfer performance in reflective projection light exposure.

### Second Embodiment

Next, a reflective projection light exposure mask according to a second embodiment is explained.

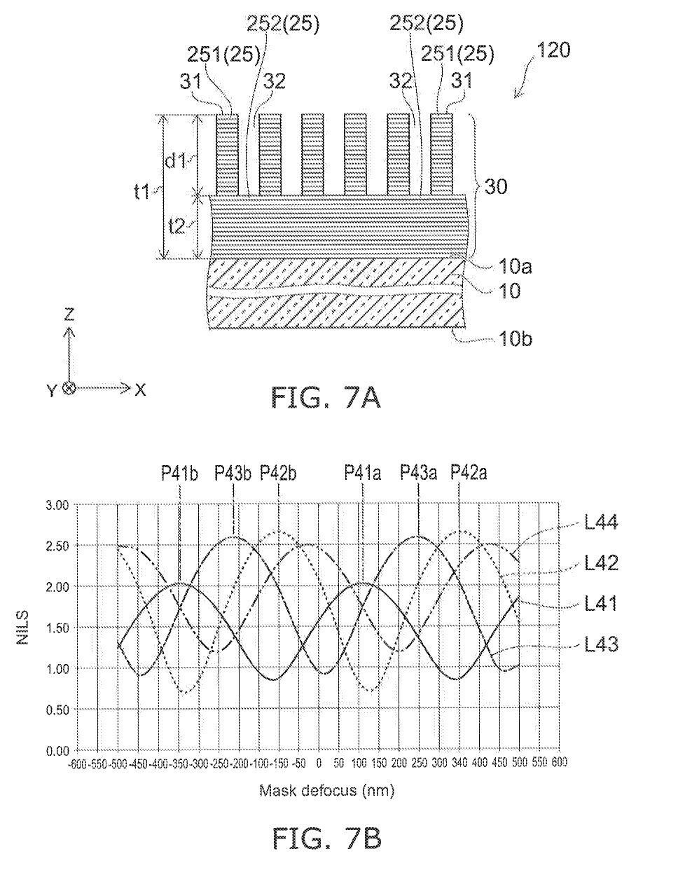

FIGS. 7A and 7B illustrate the second embodiment.

FIG. 7A shows a schematic cross-sectional view of an example of the configuration of a reflective projection light exposure mask 120 according to this embodiment. FIG. 7B shows the results of simulation of the relationship between the position of the focal point and the normalized image log slope (NILS).

As illustrated in FIG. 7A, the reflective projection light exposure mask 120 according to this embodiment includes the substrate 10 and a pattern portion 30. The pattern portion 30 is provided on the first surface 10a of the substrate 10. The pattern portion 30 includes a multilayer reflective film 25.

The pattern portion 30 includes a plurality of protruding patterns 31, and depression patterns 32 provided between the plurality of protruding patterns 31. The protruding patterns 31 and depression patterns 32 each extend in, for example, the Y direction. In other words, a line and space pattern configuration is configured by the protruding patterns 31 and the depression patterns 32. In this embodiment, a line and space pattern configuration is used as an example, but other pattern configurations (for example, an island configuration) may be used.

In the reflective projection light exposure mask 120, the protruding patterns 31 include a protruding multilayer reflective film 251 that is a portion of the multilayer reflective film 25. The depression patterns 32 include a depression multilayer reflective film 252 which is another portion of the multilayer reflective film 25. The thickness t1 of the protruding multilayer reflective film 251 is greater than the thickness t2 of the depression multilayer reflective film 252.

The depression pattern 32 is a portion that is recessed from the top surface of the protruding multilayer reflective film 251 of the protruding pattern 31 in the Z direction by the depth d1 towards the substrate 10. In other words, the difference in the thickness t1 of the protruding multilayer reflective film 251 and the thickness t2 of the depression multilayer reflective film 252 is equal to the depth d1.

The thickness t2 of the depression multilayer reflective film 252 is for example not more than ½ the thickness t1 of the protruding multilayer reflective film 251.

To manufacture the reflective projection light exposure mask 120, the multilayer reflective film 25 is formed on the first surface 10a of the substrate 10. Then, a portion of the multilayer reflective film 25 is etched using, for example, RIE. This etching is carried out to a position part way along the multilayer reflective film 25 in the Z direction. In other words, the etching is carried out to a position between the top surface of the multilayer reflective film 25 and the first surface 10a of the substrate 10. The portion that remains without being etched becomes the protruding pattern 31, and the portion removed by etching down to part way from the top surface of the multilayer reflective film 25 becomes the depression pattern 32.

In the manufacture of the reflective projection light exposure mask 120, it is not necessary to provide a separate material for the bottom of the depression patterns 22, so the manufacturing process is simplified.

In reflective projection light exposure using the reflective projection light exposure mask 120, the shadowing effect is suppressed, and a high contrast pattern image is formed.

The horizontal axis of FIG. 7B shows the position of the focal point, and the vertical axis shows the NILS. Here, the thickness of the multilayer reflective film 25 is 280 nm. Also, the NILS is represented by the following equation (2). In equation (2), W is a required dimension, Iₜₕ is an image intensity threshold to give W, and (dI/dx) is the slope of the spatial image.

NILS=W×(1/Iₜₕ)×(dI/dx) (2)

The line L41 in FIG. 7B is a line that represents an example in which the depth d1 of the depression patterns 32 is 56 nm. The line L42 is a line that represents an example in which the depth d1 of the depression patterns 32 is 196 nm. The lines L41 and L42 are included in the example of the reflective projection light exposure mask 120. The line L43 is a line that represents an example of the reflective projection light exposure mask 110 (an example in which the multilayer reflective film 25 is not included in the depression patterns 22). The line L44 is a line that represents an example of the reflective projection light exposure mask 190.

It can be seen that the NILS of the reflected image due to the reflective projection light exposure mask 110 and reflective projection light exposure mask 120 as represented by the lines L41, L42, and L43 is greater than the NILS of the reflected image due to the reflective projection light exposure mask 190 as represented by the line L44.

Also, the NILS in line L42 is greater than the NILS of lines L41 and L43. In other words, by appropriately setting the depth d1 in the depression patterns 32, a large NILS can be obtained.

In this way, by using the reflective projection light exposure mask 120, it is possible to improve the transfer performance in reflective projection light exposure.

### Third Embodiment

Next, a light exposure device according to a third embodiment is explained.

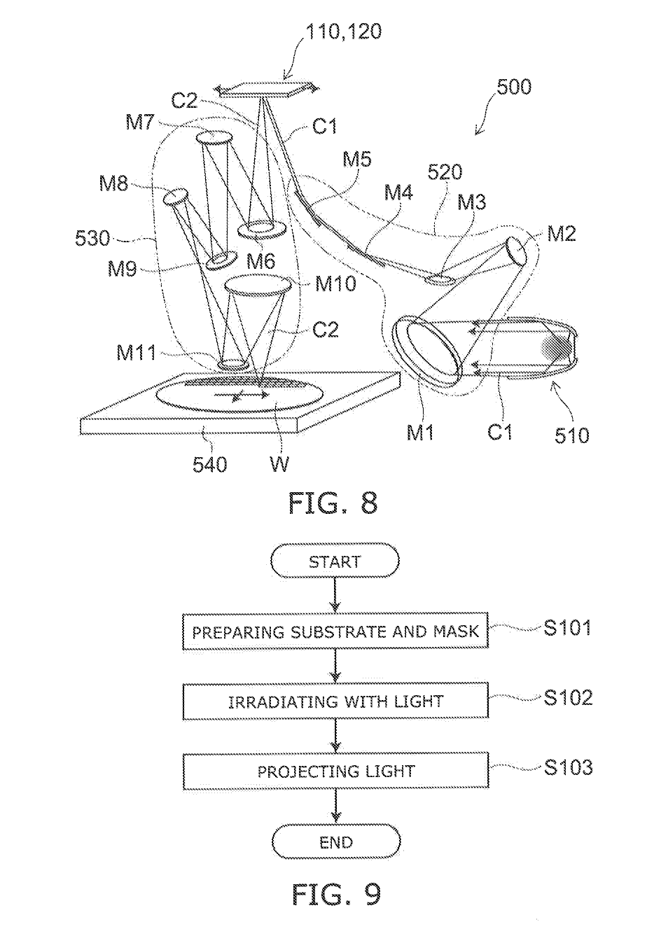

FIG. 8 is a schematic view illustrating a configuration of a light exposure device according to the third embodiment.

As illustrated in FIG. 8, a light exposure device 500 according to this embodiment includes a light source 510, a first optical system 520, and a second optical system 530.

The light source 510 emits, for example, EUV light C1. The first optical system 520 irradiates the reflective projection light exposure mask 110 and 120 with the light C1 emitted from the light source 510. The first optical system 520 is an irradiating optical system. The first optical system 520 includes, for example, a plurality of mirrors M1 through M5. Aberration of the light C1 is corrected by the plurality of mirrors M1 through M5. Also, the light C1 is focused on a predetermined position of the reflective projection light exposure mask 110 and 120 by the plurality of mirrors M1 through M5. The positions and angles of the plurality of mirrors M1 through M5 can be adjusted as appropriate.

The second optical system 530 projects light C2 reflected by the reflective projection light exposure mask 110 and 120 towards an object to be exposed to light (for example, a wafer W on which a resist is applied). The second optical system 530 is a projection optical system. The second optical system 530 includes, for example, a plurality of mirrors M6 through M11. Aberration of the light C2 is corrected by the plurality of mirrors M6 through M11. Also, the light C2 is focused on a predetermined position on the wafer W by the plurality of mirrors M6 through M11. The positions and angles of the plurality of mirrors M6 through M11 can be adjusted as appropriate.

The wafer W is mounted on a stage 540. The light exposure device 500 projects the light C2 which is light reflected by the reflective projection light exposure mask 110 and 120 onto the wafer W via the second optical system 530. When projection onto one region is completed, the stage 540 is moved. Then, the light C2 is projected onto the next region of the wafer W. By repeating this process, the light C2 is projected onto a plurality of regions on the wafer W.

The first optical system 520 sets the position of the focal point of the light C1 between the first surface 10a and the top surfaces of the protruding patterns 21 and 31 of the reflective projection light exposure mask 110 and 120. For example, as shown in FIG. 7B, in the line L43 that represents the relationship between the position of the focal point and the NILS in the reflective projection light exposure mask 110, there is a peak P43a near the focal point position 250 nm. Also, in the lines L41 and L42 that represents the relationship between the position of the focal point and the NILS in the reflective projection light exposure mask 120, there are peaks P41a and P42a near the focal point positions 110 nm and 350 nm. The focal point positions are set in accordance with these peaks P41a, P42a, and P43a.

Also, the first optical system 520 may set the position of the focal point of the light C1 on the substrate 10 side of the first surface 10a of the reflective projection light exposure mask 110 and 120. For example, as shown in FIG. 7B, in the line L43, there is a peak P43b near the focal point position −220 nm. Also, in the lines L41 and L42, there are peaks P41b and P42b near the focal point positions −340 nm and −100 nm. The focal point positions are set in accordance with these peaks P41b, P42b, and P43b.

By setting the positions of the focal points in this manner, it is possible to increase the contrast of the images of the light C2 due to the reflective projection light exposure mask 110 and 120 and exhibit sufficient transfer performance.

### Fourth Embodiment

Next, a light exposure method according to a fourth embodiment is explained.

FIG. 9 is a flowchart illustrating the light exposure method according to the fourth embodiment.

As illustrated in FIG. 9, the light exposure method according to this embodiment includes preparing a substrate and mask (step S101), irradiating with light (step S102), and projecting the light (step S103).

In preparing the substrate and mask (step S101), an object to be exposed to light, for example a wafer W, is prepared. For example, a resist is applied to the surface of the wafer W. The wafer W is mounted on the stage 540 illustrated in FIG. 8. Also, reflective projection light exposure mask 110 and 120 is prepared as a mask. The reflective projection light exposure mask 110 and 120 is fixed in a mask holder (not illustrated on the drawings) of the light exposure device 500 illustrated in FIG. 8.

Next, in irradiating with light (step S102), the reflective projection light exposure mask 110 and 120 is irradiated with a predetermined light C1. The light C1 is, for example, emitted from the light source 510 illustrated in FIG. 8, and irradiated onto the reflective projection light exposure mask 110 and 120 via the first optical system 520.

In this embodiment, when the reflective projection light exposure mask 110 and 120 is irradiated with the light C1, the position of the focal point of the light C1 is set between the first surface 10a and the top surface of the protruding pattern 21 and 31 of the reflective projection light exposure mask 110 and 120. Also, the position of the focal point of the light C1 maybe set on the substrate 10 side of the first surface 10a of the reflective projection light exposure mask 110 and 120.

Next, in projecting the light (step S103), the light C2 which is the light C1 reflected by the reflective projection light exposure mask 110 and 120 is projected onto the wafer W which is the object to be exposed to light. The light C2 is projected onto the wafer W via the second optical system 530 illustrated in FIG. 8, for example. In this way, the image of the reflected light is transferred to the resist on the wafer W by the reflective projection light exposure mask 110 and 120.

According to the light exposure method of this embodiment, it is possible to improve the contrast of the image of the light C2 due to the reflective projection light exposure mask 110 and 120 and exhibit sufficient transfer performance.

As explained above, according to the reflective projection light exposure mask, light exposure method, and light exposure device of this embodiment, it is possible to improve the transfer performance of the pattern image.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light exposure method, comprising:
irradiating light on a reflective projection light exposure mask, the reflective projection light exposure mask including a substrate and a pattern portion, the substrate having a first surface, the pattern portion having a multilayer reflective film provided on the first surface of the substrate, the pattern portion including a plurality of protruding patterns and depression patterns provided between the plurality of protruding patterns; and
irradiating an object to be exposed to light with reflected light by reflecting the light by the reflective projection light exposure mask.

2. The light exposure method according to claim 1, wherein the irradiating of light on the reflective projection light exposure mask includes setting a position of the focal point of the light between the first surface of the reflective projection light exposure mask and a top surface of the protruding pattern.

3. The light exposure method according to claim 1, wherein the irradiating of light on the reflective projection light exposure mask includes setting a position of the focal point of the light on the substrate side of the first surface of the reflective projection light exposure mask.

4. The light exposure method according to claim 1, wherein the irradiating of light on the reflective projection light exposure mask includes using the reflective projection light exposure mask in which the first surface is exposed from the bottom of the depression patterns.

5. The light exposure method according to claim 1, wherein the irradiating of light on the reflective projection light exposure mask includes using the reflective projection light exposure mask in which,
the protruding patterns include a protruding multilayer reflective film that is a portion of the multilayer reflective film,
the depression patterns include a depression multilayer reflective film that is another portion of the multilayer reflective film, and
the thickness of the protruding multilayer reflective film is greater than the thickness of the depression multilayer reflective film.

6. The light exposure method according to claim 1, wherein the light is extreme ultraviolet light.

7. A light exposure device, comprising;
a light source;
a first optical system that irradiates light emitted from the light source towards a reflective projection light exposure mask; and
a second optical system that projects light reflected by the reflective projection light exposure mask towards an object to be exposed to light,
the reflective projection light exposure mask including a substrate and a pattern portion, the substrate having a first surface, the pattern portion having a multilayer reflective film provided on the first surface of the substrate, the pattern portion including a plurality of protruding patterns and depression patterns provided between the plurality of protruding patterns.

8. The light exposure device according to claim 7, wherein the first surface is exposed from the bottom of the depression patterns of the reflective projection light exposure mask.

9. The light exposure device according to claim 7, wherein the protruding patterns include a protruding multilayer reflective film that is a portion of the multilayer reflective film,
the depression patterns include a depression multilayer reflective film that is another portion of the multilayer reflective film, and
the thickness of the protruding multilayer reflective film is greater than the thickness of the depression multilayer reflective film.

10. The light exposure device according to claim 7, wherein the light source emits extreme ultraviolet light.

11. A reflective projection light exposure mask, comprising: a substrate having a first surface, and
a pattern portion that includes a plurality of protruding patterns having a multilayer reflective film provided on the first surface of the substrate, and depression patterns provided between the plurality of protruding patterns.

12. The reflective projection light exposure mask according to claim 11, wherein the first surface is exposed from the bottom of the depression patterns.

13. The reflective projection light exposure mask according to claim 11, wherein the protruding patterns include a protruding multilayer reflective film that is a portion of the multilayer reflective film,
the depression patterns include a depression multilayer reflective film that is another portion of the multilayer reflective film, and
the thickness of the protruding multilayer reflective film is greater than the thickness of the depression multilayer reflective film.

14. The reflective projection light exposure mask according to claim 11, wherein the multilayer reflective film effectively reflects extreme ultraviolet light.

15. The reflective projection light exposure mask according to claim 11, wherein the multilayer reflective film includes a plurality of first films and a plurality of second films disposed alternately.

16. The reflective projection light exposure mask according to claim 15, wherein the plurality of first films includes Mo, and
the plurality of second films includes Si.

17. The reflective projection light exposure mask according to claim 15, wherein the thickness of each film of the plurality of first films is not less than 3 nanometers and not more than 4 nanometers, and
the thickness of each film of the plurality of the second films is not less than 3 nanometers and not more than 4 nanometers.
